(19) United States
(12) Patent Application Publication
(10) Pub. No.: US 2016/0189958 A1
(43) Pub. Date: Jun. 30, 2016

(54) HETEROEPITAXIAL GROWTH OF Ge-Sn ALLOYS

(71) Applicant: THE BOARD OF TRUSTEES OF THE UNIVERSITY OF ARKANSAS, Little Rock, AR (US)

(72) Inventors: Aboozar MOSLEH, Fayetteville, AR (US); Shui-Qing YU, Fayetteville, AR (US); Hameed A. NASEEM, Fayetteville, AR (US); Murtadha ALHER, Fayetteville, AR (US); Larry C. COUSAR, Fayetteville, AR (US)

(21) Appl. No.: 14/984,478

(22) Filed: Dec. 30, 2015

Related U.S. Application Data
(60) Provisional application No. 62/097,914, filed on Dec. 30, 2014.

(51) Int. Cl. H01L 21/02

(52) U.S. Cl. CPC H01L 21/02535; H01L 21/02381; H01L 21/0262

(57) ABSTRACT

Heteroepitaxial methods are described herein for the growth of germanium-tin alloy layers directly on silicon substrates. A method of heteroeptiaxial growth of a germanium-tin alloy layer comprises placing a silicon substrate in a cold wall ultra-high vacuum chemcial vapor deposition chamber and depositing the germanium-tin alloy layer directly on the silicon substrate from a gaseous mixture in the deposition chamber, the gaseous mixture comprising a germanium source and a tin source.

### RELATED APPLICATION DATA

The present application claims priority pursuant to 35 U.S.C. §119(e) to U.S. Provisional Patent Application Ser. No. 62/097,914, filed Dec. 30, 2014, which is incorporated herein by reference in its entirety.

### STATEMENT OF GOVERNMENT RIGHTS

The present invention was made with government support under National Science Foundation Grant Number EPS-1003970 and Defense Advanced Research Projects Agency (DARPA) Grant Number W911NF-13-1-0196. The United States Government has certain rights to the present invention.

### FIELD

The present invention relates to heteroepitaxially grown structures and, in particular, to Ge—Sn alloys grown directly on silicon substrates.

### BACKGROUND

The discovery and development Ge₁₋ₓSnₓ epitaxy technology has enabled silicon photonics to be explored in a different scope of material platform. The ability of bandgap engineering by varying Sn mole fraction along with its compatibility to complementary metal oxide-semiconductor (CMOS) processes have paved the way for highly competetive Si-based near and mid-infrared optoelectronic devices. Recent reports on the fabrication and characterization of high performance Ge₁₋ₓSnₓ devices such as modulators, photodetectors and light emiting diodes (LEDs) show great potential of Ge₁₋ₓSnₓ being adopted by industry in the near future. Cutting-edge reports on Ge₁₋ₓSnₓ, achieving a direct band-gap group IV alloy is a turning point for the technology to be pursued for the demonstration of efficient group IV laser.

A variety of challenges exist for the growth of Ge₁₋ₓSnₓ alloys on silicon substrates including large lattice mismatch, low solid solubility of tin in germanium and low thermal stability of diamond lattice tin (α-Sn). These challenges can be largely overcome through the use of germanium buffer layers and/or the employment of specialized germanium and tin reactants at non-equilibrium conditions. However, such solutions are generally commercially undesirable as they increase time and cost of Ge₁₋ₓSnₓ alloy fabrication.

### SUMMARY

In one aspect, methods of heteroepitaxial growth of germanium-tin alloys are described herein which, in some embodiments, offer efficiencies not found in prior fabrication techniques. For example, methods described herein obviate germanium buffer layers and employ lower cost gaseous reactants. A method described herein comprises placing a silicon substrate in a cold wall ultra-high vacuum chemical vapor deposition chamber and depositing a germanium-tin alloy layer directly on the silicon substrate from a gaseous mixture in the deposition chamber, the gaseous mixture comprising a germanium source and a tin source. In some embodiments, substrate deposition temperature is less than 400° C. Further, germane (GeH₄) can be employed as the germanium source. Additionally, a silicon source can be added to the gaseous mixture according to some methods described herein for the heteroepitaxial growth of silicon-germanium-tin alloys.

These and other embodiments are described in greater detail in the detailed description which follows.

### BRIEF DESCRIPTION OF THE DRAWINGS

FIG. 1 illustrates a cold wall UHV-CVD system according to one embodiment described herein.

FIG. 2 provides X-ray diffractograms of Ge—Sn alloy layers deposited according to methods described herein.

FIG. 3 is a transmission electron microscopy (TEM) image illustrating epitaxial growth of GeSn on a Si substrate according to a method described herein.

FIG. 4(a) illustrates Sn incorporation into Ge as a function of deposition pressure in methods described herein, and FIG. 4(b) illustrates Sn incorporation as a function of Ge:Sn flow ratio in methods described herein.

FIG. 5(a) illustrates Raman spectra of Ge—Sn alloy layers fabricated according to a method described herein, and FIG. 5(b) illustrates experimentally measured Raman shifts compared with theoretical calculations.

FIG. 6(a) provides photoluminescence spectra of Ge—Sn alloy layers fabricated according to a method described herein, and FIG. 6(b) illustrates bowed Vegard's law interpolation for the direct (solid line) and indirect (dashed line) bandgaps of Ge—Sn alloy at differing Sn composition. FIG. 7 illustrates normalized spectral response of Ge_{0.96}Sn_{0.04} photoconductors at room temperature as a function of wavelength according to one embodiment described herein.

### DETAILED DESCRIPTION

Embodiments described herein can be understood more readily by reference to the following detailed description and examples and their previous and following descriptions. Elements, apparatus and methods described herein, however, are not limited to the specific embodiments presented in the detailed description and examples. It should be recognized that these embodiments are merely illustrative of the principles of the present invention. Numerous modifications and adaptations will be readily apparent to those of skill in the art without departing from the spirit and scope of the invention.

Heteroepitaxial methods are described herein for the growth of germanium-tin alloy layers directly on silicon substrates. A method of heteroeptiaxial growth of a germanium-tin alloy layer comprises placing a silicon substrate in a cold wall ultra-high vacuum chemcial vapor deposition chamber and depositing the germanium-tin alloy layer directly on the silicon substrate from a gaseous mixture in the deposition chamber, the gaseous mixture comprising a germanium source and a tin source.

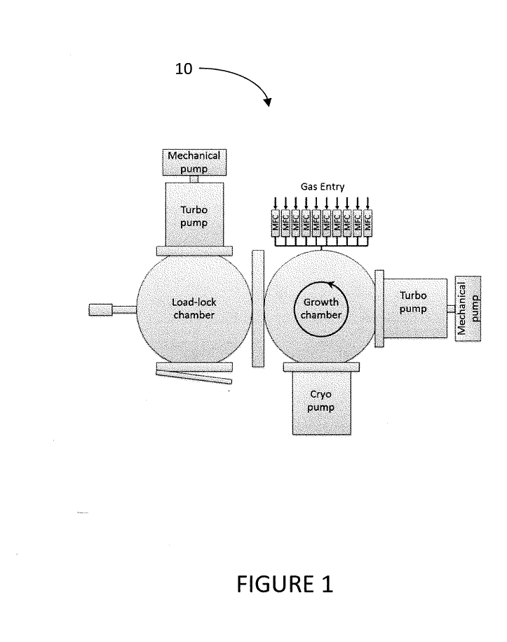

FIG. 1 illustrates a cold wall UHV-CVD system according to one embodiment described herein. In being a UHV system, the deposition or growth chamber generally achieves pressures less than 10⁻⁷ Torr. However, lower pressures are possible as described below. The cold wall UHV-CVD system (10) of FIG. 1 comprises a load-lock chamber and deposition or growth chamber. The load-lock chamber is operable to achieve a base pressure of 10⁻⁸ Torr via the attached turbo-molecular pump. Moreover, the deposition or growth chamber is operable to exhibit a base pressure of 10⁻¹⁰ Torr through use of turbo-molecular and cryogenic pumps. Due to the low growth temperatures employed by methods described herein, the cryogenic pump is used to remove oxygen and water vapor that may oxidize surfaces of the silicon substrate.

The silicon substrate is loaded into the load-lock chamber and transferred to the deposition or growth chamber. Prior to loading, the silicon substrate may undergo oxide stripping by exposure to hydrofluoric acid followed by nitrogen drying to impart a hydrogen passivated surface. The silicon substrate is heated to acceptable temperature for Ge—Sn deposition by a heating stage. For example, the silicon substrate can be heated to a temperature of 200° C. to 400° C., in some embodiments. Gaseous germanium source and gaseous tin source are provided to the growth chamber via mass flow controllers. Gaseous germanium source and gaseous tin source, in some embodiments, mix prior to the inlet of the deposition chamber. Alternatively, gaseous germanium source and gaseous tin source can remain separate until introduction in the deposition chamber. Moreover, carrier gas, such as H₂, is optional and generally not used due to etching enhancements discussed herein.

Any germanium source and tin source may be employed operable to deposit Ge—Sn alloy layers under the cold wall UHV-CVD conditions described herein. While operable with methods described herein, higher order germanes, such as digermane (Ge₂H₆), are not required. Advantageously, GeH₄ can serve as the germanium source leading to cost efficiencies. Moreover, the tin source can include one or more tin chlorides. In some embodiments, tin chloride is SnCl₄. Use of tin chloride(s) can realize additional cost efficiencies in comparison other possible tin sources including deuterated stannane (SnD₄) and alkyl tin complexes, such as tetramethyl tin [Sn(CH₃)₄].

Introduction of gaseous germanium and tin sources provides a preferable deposition pressure of 0.1 Torr to 1.0 Torr. Additionally, the germanium source and tin source can be present in the gaseous mixture in any ratio (Ge:Sn) not inconsistent with the objectives of the present invention. For example, the Ge:Sn ratio can range from 1 to 5. Further, depending on growth parameters including Ge:Sn ratio and deposition pressure, a germanium-tin alloy growth rate of 3 nm/min to 20 nm/min can be achieved. Germanium-tin alloy layers can be grown to any desired thickness. In some embodiments, a germanium-tin alloy layer has a thickness of 0.01 μm to 1 μm. In other embodiments, a germanium-tin alloy layer has a thickness greater than 1 μm.

The deposited germanium-tin alloy layer can be of the formula Ge₁₋ₓSnₓ, wherein x ranges from 0.005-0.25. In some embodiments, x ranges from 0.01-0.10. Tin can be distributed uniformly or substantially uniformly in the germanium host. Additionally, the germanium-tin alloy layer can be free of tin precipitate. Germanium-tin alloy layers deposited according to methods described herein can be at least 95% relaxed. In some embodiments, germanium-tin alloy layers are 96-99% relaxed or fully relaxed.

Further, a silicon source can be added to the gaseous mixture according to some methods described herein for the heteroepitaxial growth of silicon-germanium-tin alloys directly on silicon substrates. Introduction of SiH₄ along with GeH₄ and SnCl₄, for example, has resulted in growth of Si_{y}Ge_{1-x-y}Snₓ alloys. The flow ratio of SiH₄ to GeH₄ was varied from 0.1 to 1. Si incorporation in GeSn films were ranging from 1-5% (y ranging from 0.01-0.05).

These and other embodiments are further illustrated by the following non-limiting examples.

### EXAMPLE 1

### Fabrication and Characterization of Ge₁₋₁Snₓ Films

Growth—A cold wall UHV-CVD system as illustrated in FIG. 1 was provided. The system comprised a load-lock chamber with a base pressure of 10⁻⁸ Torr and a deposition chamber whose base pressure reaches 10⁻¹⁰ Torr using the turbo-molecular and cryogenic pumps. Due to low temperature growth of the films, removal of oxygen and water vapor is critical which was achieved by using a cryogenic pump. The turbo-molecular pumps are backed by mechanical pumps. The heating stage consisted of a pyrolitic graphite heater with a thermocouple placed at the same distance away from the heater as the wafer. The sample holder rotated up to 80 rpm for uniform film growth. Reactant gas flow was through a side entry port, controlled by mass flow controllers (MFCs).

Germanium-tin films were grown on 4″ (001) p-type Si substrates with 5-10 Ω·cm resistivity. Prior to loading, the silicon substrates were cleaned in a two-step process: 1. Piranha etch solution [H₂SO₄:H₂O₂ (1:1)], 2. Oxide strip HF dipping [H₂O:HF (10:1)] followed by nitrogen blow drying. The final oxide strip step was not followed by a water rinse as it reduces the life-time of hydrogen passivation and exposes the surface to ambient oxygen. The experiments were carried out at reduced pressures of 0.1, 0.3, 0.5, 1, 1.5 and 2 Torr and at temperatures as low as 300° C. Germane (GeH₄) and stannic chloride (SnCl₄) were used as the precursors for Ge₁₋ₓSnₓ growth. The gas flow ratio (GeH₄/SnCl₄) was set to 5, 3.3, 2.5 and 1.6. Depending on the growth parameters such as gas flow ratio and deposition pressure, a growth rate of 20 nm/min to 3.3 nm/min was achieved.

Characterization—Analyses of Sn mole fraction, lattice constant, growth quality and strain in the Ge₁₋ₓSnₓ films were conducted using a high resolution X-ray diffractometer. High Resolution TEM (TITAN) with an accelerating voltage of 300 kV was used to investigate crystal orientation and defects in the grown epi-layers as well as determining the thicknesses of the samples. Surface morphology of the samples was investigated by a scanning electron microscope equipped with energy-dispersive X-ray spectroscopy. Room temperature PL measurements were carried out using a 690 nm excitement laser. The signal was collected and projected onto a gating-based spectrometer equipped with a thermoelectric-cooled PbS detector (cut-off at 3 μm) for spectral analysis. Photoconductor devices were characterized by using a tungsten white light source, a Fourier transform infrared spectroscopy system and a Keithley 236 source-measure unit.

Table I details the six germanium-tin alloy films deposited on silicon substrates according to the method of the present example.

TABLE I
Ge₁₋ₓSnₓ Films on Si Substrates

| | Sn | α_{∥} | α_{⊥} | α | Relaxation | Thickness |
|---|---|---|---|---|---|---|
| Sample | (at. %) | (nm) | (nm) | (nm) | % | (nm) |
| 1 | 1.2 | 5.666 | 5.671 | 5.668 | 98 | 615 |
| 2 | 2.1 | 5.673 | 5.679 | 5.676 | 98 | 423 |
| 3 | 2.9 | 5.678 | 5.687 | 5.682 | 97 | 295 |
| 4 | 4.2 | 5.689 | 5.695 | 5.692 | 98 | 207 |
| 5 | 5.8 | 5.699 | 5.712 | 5.706 | 97 | 532 |
| 6 | 7.0 | 5.715 | 5.719 | 5.717 | 99 | 108 |

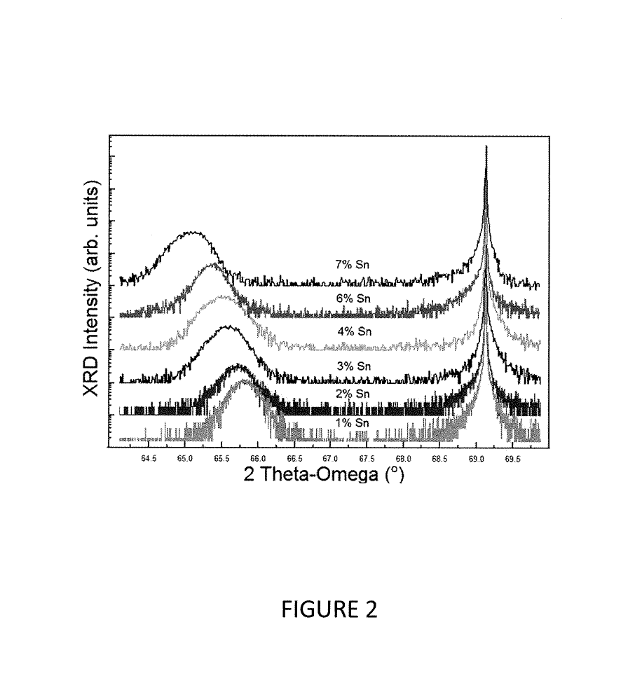

A 2θ-ω XRD scan was performed from the symmetric (004) plane to obtain the out-of plane lattice constant of the Ge₁₋ₓSnₓ films. FIG. 2 shows the peak at 69° corresponding to a satisfaction of the Bragg condition by Si (001) substrate, and the peaks at lower angles of 65-66° due to larger lattice size of the Ge₁₋ₓSnₓ layers. The difference in the position of Ge₁₋ₓSnₓ peaks is due to the difference in the Sn mole fractions of Ge₁₋ₓSnₓ layers. Different compositions were achieved from 1% to 7%; however, the 5% growth did not display desirable crystal quality (not shown here). The broadening of the Ge₁₋ₓSnₓ peaks was attributed to the variation of thin film thickness as compared to the Si substrate as well as the quality of the film in terms of mosaicity and strain relaxation. Full width at half maximum (FWHM) of the Ge₁₋ₓSnₓ peaks are between 0.28 for 1%-Sn film and 0.36 for 7%-Sn film. The change in FWHM depends on various factors such as film thickness, relaxation and quality and there was no trend showing that the FWHM of the peaks change as the Sn composition increases.

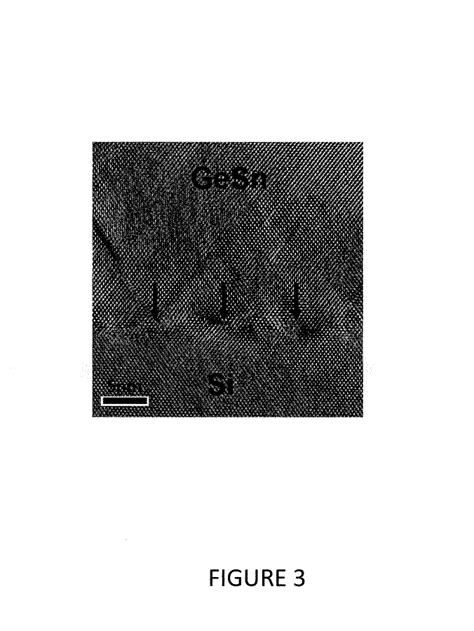

In order to calculate the total lattice constant and the strain in the film, an asymmetric reciprocal space mapping (RSM) from (−2 −2 4) plane was performed. The RSM scans provided measurement of the in-plane (a_{∥}) and out-of-plane (a_{⊥}) lattice constants of Ge₁₋ₓSnₓ alloys. The total lattice constant a₀^{GeSn} was calculated by taking into account the elastic constants of Ge₁₋ₓSnₓ. Knowing the total lattice constant, the Sn mole fractions were calculated through Vegard's law with the bowing factor (b=0.0166 Å). As provided in Table I, all the Ge₁₋ₓSnₓ films exhibited relaxation in excess of 95%. Ge₁₋ₓSnₓ films were almost fully relaxed due to large lattice mismatch between Si (5.431 Å) and Ge₁₋ₓSnₓ (above 5.658 Å) and small critical thickness. The strain has been mainly relieved through formation of misfit dislocations including Lomer misfit dislocation. The cross-sectional TEM image in FIG. 3 shows formation of such dislocations at the Ge₁₋ₓSnₓ/Si interface. The TEM image also confirms the Ge₁₋ₓSnₓ films were fully epitaxial. Further, no precipitation of Sn was observed on the Ge₁₋ₓSnₓ films indicating robust and stable growth.

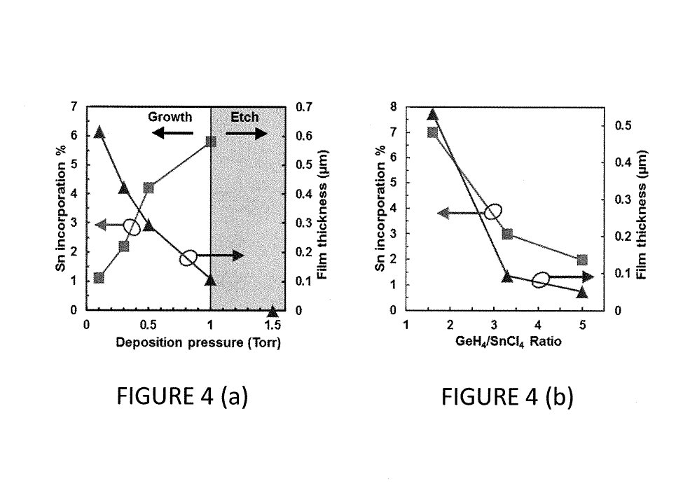

As illustrated in FIG. 4(a), growth was observed at deposition pressure of 0.1 Torr to 1.0 Torr. No growth was observed for pressures of 1.5 and 2.0 Torr. Incorporation of Sn in the Ge lattice was increased by raising the pressure due to higher residence time of the germanium and tin gaseous reactants in the deposition chamber. Meanwhile, HCl etched more of the Ge₁₋ₓSnₓ films at higher deposition pressures. In order to fabricate high Sn content films, lower GeH₄/SnCl₄ flow ratio was required as illustrated in FIG. 4(b). Due to the dominance of etching for higher GeH₄/SnCl₄ flow ratios, the films were mostly etched and the film thickness was less than 100 nm.

Introduction of carrier gases has different effects on the growth of Ge₁₋ₓSnₓ films Hydrogen changes the balance in the reaction to produce more HCl. Consequently, the GeH₄/SnCl₄ ratio at which the Ge₁₋ₓSnₓ films were depositing will not result in growth when hydrogen is introduced in the chamber. In addition, introduction of nitrogen and argon as carrier gases will reduce the activation energy of the growth. Although reduction of activation energy enables easier breakdown of the molecules on the surface and enhances the growth quality and growth rate, it would prepare the conditions for easier etch due to the presence of an etchant agent. Therefore, presence of carrier gases pushes the competition between growth and etching towards etching, resulting in film etching at even lower flow rates of carrier gases when the flow rate of SnCl₄ is of the same order of GeH₄.

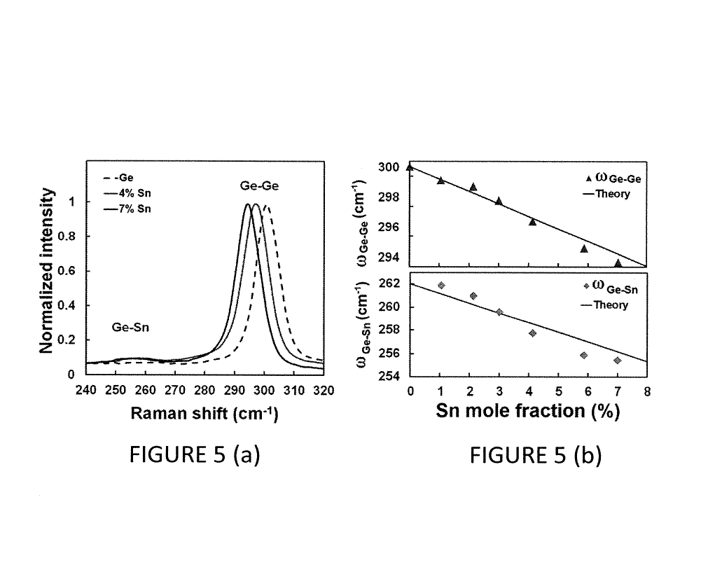

The Ge₁₋ₓSnₓ films were further investigated by Raman spectroscopy in order to analyze the crystal structure. Room temperature Raman spectra of the grown Samples 1-6 as well as a Ge reference sample are plotted in FIG. 5(a). The Ge—Ge LO peak was observed at 300 cm⁻¹ for the Ge reference sample while the Ge—Ge peak in the Ge₁₋ₓSnₓ films was shifted to lower wavenumbers due to the change in bonding energy of Ge—Ge by incorporation of Sn atoms. The intensity of the Ge—Ge LO peak at 300 cm⁻¹ is normalized for all the samples for comparison of the peak positions. Besides the main Ge—Ge peak, Raman spectra of Ge₁₋ₓSnₓ films showed other peaks that are induced as a result of Sn incorporation. The Ge—Sn LO peaks for different Sn mole fractions were observed at 250-260 cm⁻¹ in the films. A second peak of Ge—Sn is observed at 285 cm⁻¹, which can be seen as a shoulder of Ge—Ge main peak.

The peak positions were obtained by Lorentzian fitting to find the exact position for further analysis. The shift in the Ge—Ge LO peak depends on both strain and Sn composition of the films. Theoretical calculations for Δω are different for strain relaxed films and strained films for different Sn (x) content (Δω_{Ge—Ge}(x)=bx cm⁻¹). The Ge—Ge peak is expected to shift by a factor of b=−30.30 for a strained alloy while this factor varies to b=−83.10 for a strain relaxed film. FIG. 5(b) shows the experimental data obtained for Ge—Ge and Ge—Sn Raman shift from the sample compared with the theoretical calculations. The peak shifts matched fairly well with the theoretical calculations.

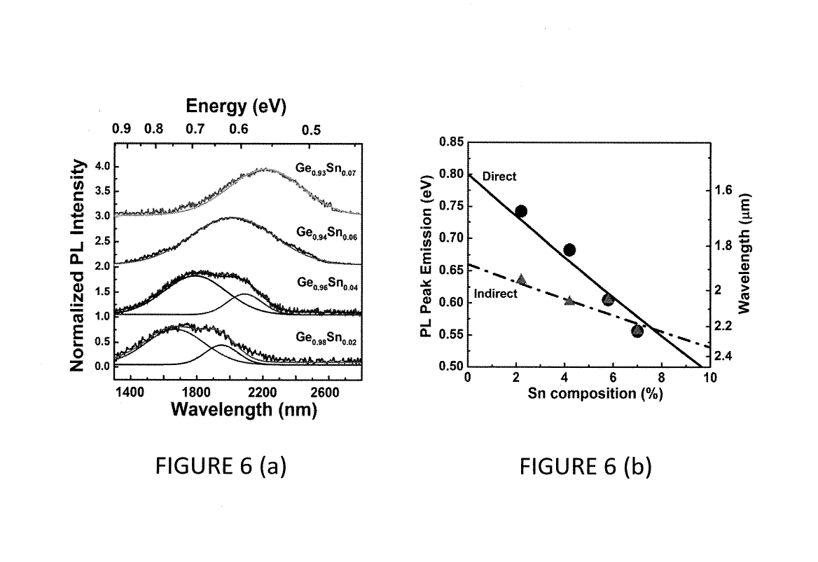

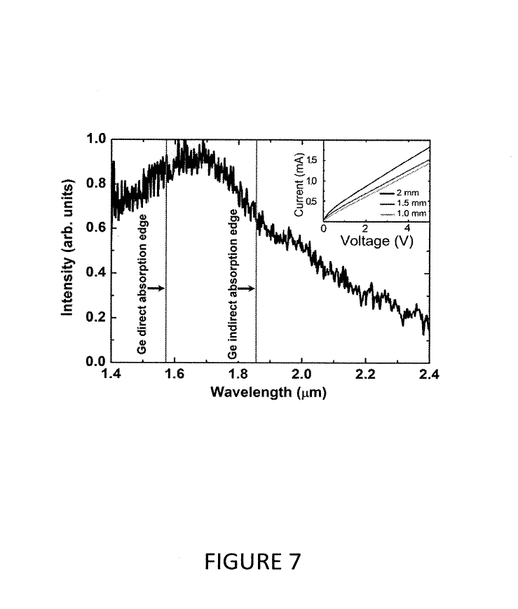

Germanium has an indirect bandgap in the L valley with the energy of 0.644 eV and a direct bandgap at the F point with 0.8 eV energy at room temperature. Incorporation of Sn in Ge lattice lowers the conduction band edge at the F-point at a faster rate than that at the L-point. Photoluminescence measurements on Ge₁₋ₓSnₓ samples allowed determination of the bandgap edge for the various Sn compositions. FIG. 6 depicts room temperature PL intensity spectra for as-grown Ge₁₋ₓSnₓ films with 2%, 4%, 6% and 7% Sn mole fractions. As indicated in FIG. 6(a), increase of the Sn mole fraction results in a bandgap reduction. Both direct and indirect PL peaks exhibit red-shift with Sn compositions increase from 2% to 7%. A Gaussian fitting function was employed to extract the PL peak positions of both direct and indirect transitions. In Ge_{0.94}Sn_{0.06} and Ge_{0.93}Sn_{0.07} samples, the energies difference between direct and indirect transitions were very small, therefore the PL emissions from these indirect and direct transitions cannot be identified. A temperature dependent study is needed to differentiate the direct and indirect peak positions which will be reported in future. The PL peaks from the samples with 2%, 4%, 6%, and 7% Sn compositions are shown in FIG. 6(b) as solid symbols. The solid and the dashed lines show the direct and indirect bandgap energies based on bowed Vegard's law for the relaxed Ge₁₋ₓSnₓ alloy, respectively. Since the Ge₁₋ₓSnₓ films are almost strain-free, as confirmed by XRD measurements, the experimental results closely follow the predicted values from Vegard's law.

In order to measure the spectral response of the grown Ge₁₋ₓSnₓ layers, photoconductor devices were fabricated and characterized. Standard photolithography techniques were employed to fabricate the photoconductors. The Ge₁₋ₓSnₓ mesas were defined in different sizes of ×1, 1.5×1.5 and 2×2 mm. The current-voltage (I-V) characteristic of the metal contacts was checked and a linear I-V behavior was observed. The inset of FIG. 7 shows the I-V behavior for different mesa sizes.

Optical characterization of the fabricated photoconductors was conducted by focusing a normally incident tungsten white light source onto the device. The spectral response was measured using a Fourier transform infrared spectrometer. The room temperature spectral response of the 4% sample in FIG. 7 shows an extended response compared to that of Ge, whose absorption edges are marked with red lines in FIG. 7. The extended response is attributed to the incorporation of Sn, which narrowed the bandgap and therefore enhanced the absorption coefficient at longer wavelength than Ge. According to bandgap calculation shown in FIG. 6, the direct and indirect bandgap energies of 4% Sn sample are 0.68 and 0.60 eV (1.82 and 2.06 μm), respectively. Thereby the photo response beyond 2.1 μm is the absorption tail which may due to the impurities.

Various embodiments of the invention have been described in fulfillment of the various objects of the invention. It should be recognized that these embodiments are merely illustrative of the principles of the present invention. Numerous modifications and adaptations thereof will be readily apparent to those skilled in the art without departing from the spirit and scope of the invention.

1. A method of heteroepitaxial growth of a germanium-tin alloy layer comprising:
placing a silicon substrate in a cold wall ultra-high vacuum chemical vapor deposition chamber; and
depositing the germanium-tin alloy layer directly on the silicon substrate from a gaseous mixture in the deposition chamber, the gaseous mixture comprising a germanium source and a tin source.

2. The method of claim 1, wherein substrate deposition temperature is less than 400° C.

3. The method of claim 1, wherein substrate deposition temperature is 200° C. to 400° C.

4. The method of claim 1, wherein the germanium source comprises GeH₄.

5. The method of claim 4, wherein the tin source comprises a tin chloride.

6. The method of claim 5, wherein the tin chloride is SnCl₄.

7. The method of claim 1, wherein the gaseous mixture does not include a carrier gas.

8. The method of claim 1, wherein the deposition pressure is 0.1 Torr to 1 Torr.

9. The method of claim 1, wherein the ratio of germanium source to tin source (Ge:Sn) in the gaseous mixture ranges from 1 to 5.

10. The method of claim 1, wherein the germanium-tin alloy layer has tensile stress.

11. The method of claim 1, wherein the germanium-tin alloy layer has compressive stress.

12. The method of claim 1, wherein the germanium-tin alloy is of the formula Ge₁₋ₓSnₓ, wherein x ranges from 0.005-0.25.

13. The method of claim 12, wherein x ranges from 0.01-0.10.

14. The method of claim 1, wherein the silicon substrate is loaded into a load-lock chamber prior to placement in the deposition chamber.

15. The method of claim 14, wherein the load-lock chamber is provided a pressure less than 10⁻⁷ Torr.

16. The method of claim 1, wherein the deposition chamber has a base pressure less than 10⁻⁸ Torr.

17. The method of claim 1, wherein the germanium-tin alloy is free of tin precipitate.

18. The method of claim 1, wherein the germanium-tin alloy layer is at least 95% relaxed.

19. The method of claim 1, wherein tin is uniformly distributed in the germanium-tin alloy layer.
